(19) United States
(12) Patent Application Publication
(10) Pub. No.: US 2025/0275233 A1
(43) Pub. Date: Aug. 28, 2025

(54) STACKED STRUCTURES WITH SPLIT DEVICE LAYERS

(71) Applicant: International Business Machines Corporation, Armonk, NY (US)

(72) Inventors: James P Mazza, Saratoga Springs, NY (US); Ruilong Xie, Niskayuna, NY (US); Koichi Motoyama, Clifton Park, NY (US); Nicholas Anthony Lanzillo, Wynantskill, NY (US)

(21) Appl. No.: 18/586,753

(22) Filed: Feb. 26, 2024

(51) Int. Cl. H01L 27/088; H01L 21/8234; H01L 29/06; H01L 29/417; H01L 29/423; H01L 29/66; H01L 29/775; H01L 29/786

(52) U.S. Cl. CPC H10D 84/83; H10D 30/014; H10D 30/43; H10D 30/6735; H10D 30/6757; H10D 62/121; H10D 64/254; H10D 84/0151; H10D 84/038

(57) ABSTRACT

A semiconductor device includes a multi-stacked transistor structure comprising a first stacked transistor structure and a second stacked transistor structure. The first stacked transistor structure includes a first lower transistor device and a first upper transistor device, and the second stacked transistor structure includes a second lower transistor device, a second upper transistor device, and a third upper transistor device.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments described herein provide techniques for stacked device structures with split device layers.

In one embodiment, a semiconductor device includes a multi-stacked transistor structure including a first stacked transistor structure includes a first lower transistor device and a first upper transistor device and a second stacked transistor structure including a second lower transistor device, a second upper transistor device, and a third upper transistor device.

In another embodiment, a semiconductor device comprises a first stacked field-effect transistor structure comprising a first lower field-effect transistor device and a first upper field-effect transistor device and a second stacked field-effect transistor structure comprising a second lower field-effect transistor device, a second upper field-effect transistor device, and a third upper field-effect transistor device. The second upper field-effect transistor device and the third upper field-effect transistor device include a plurality of channel layers, each of the channel layers being surrounded by a first gate cut portion and one or more gate regions.

In another embodiment, a method includes forming first and second stacked field-effect transistor device structures, where the first stacked field-effect transistor device structure comprises a first plurality of channel layers corresponding to a first upper field-effect transistor device and a first lower field-effect transistor device, and the second stacked field-effect transistor device structure comprises a second plurality of channel layers corresponding to a second upper field-effect transistor device and a second lower field-effect transistor device. The method includes forming a first gate cut portion disposed between the first and second stacked field-effect transistor device structures. The method also includes the second upper field-effect transistor device into a third upper field-effect transistor device and a fourth upper field-effect transistor device, wherein the dividing comprises dividing the channels layers corresponding to the second upper field-effect transistor device and forming a second gate cut portion between the third upper field-effect transistor device and the fourth upper field-effect transistor device.

These and other features and advantages of embodiments described herein will become more apparent from the accompanying drawings and the following detailed description.

### BRIEF DESCRIPTION OF THE DRAWINGS

FIG. 1 depicts a top view of a semiconductor structure with lines X, Y1, and Y2 on which the cross-sectional views of FIGS. 2A-8C are based, according to an illustrative embodiment.

FIG. 2A depicts a first cross-sectional view corresponding to line X in FIG. 1 illustrating the semiconductor structure of FIG. 1, according to an illustrative embodiment.

FIG. 2B depicts a second cross-sectional view corresponding to line Y1 in FIG. 1 illustrating the semiconductor structure of FIG. 1, according to an illustrative embodiment.

FIG. 2C depicts a second cross-sectional view corresponding to line Y2 in FIG. 1 illustrating the semiconductor structure of FIG. 1, according to an illustrative embodiment.

FIG. 3A depicts a first cross-sectional view corresponding to the line X in FIG. 1 following nanosheet layer patterning and isolation region formation, according to an illustrative embodiment.

FIG. 3B depicts a second cross-sectional view corresponding to the line Y1 in FIG. 1 following nanosheet layer patterning and isolation region formation, according to an illustrative embodiment.

FIG. 3C depicts a third cross-sectional view corresponding to the line Y2 in FIG. 1 following nanosheet layer patterning and isolation region formation, according to an illustrative embodiment.

FIG. 4A depicts a first cross-sectional view corresponding to the line X in FIG. 1 following dummy gate formation, according to an illustrative embodiment.

FIG. 4B depicts a second cross-sectional view corresponding to the line Y1 in FIG. 1 following dummy gate formation, according to an illustrative embodiment.

FIG. 4C depicts a third cross-sectional view corresponding to the line Y2 in FIG. 1 following dummy gate formation, according to an illustrative embodiment.

FIG. 5A depicts a first cross-sectional view corresponding to the line X in FIG. 1 following selective removal of a sacrificial semiconductor layer, according to an illustrative embodiment.

FIG. 5B depicts a second cross-sectional view corresponding to the line Y1 in FIG. 1 following selective removal of a sacrificial semiconductor layer, according to an illustrative embodiment.

FIG. 5C depicts a third cross-sectional view corresponding to the line Y2 in FIG. 1 following selective removal of a sacrificial semiconductor layer, according to an illustrative embodiment.

FIG. 6A depicts a first cross-sectional view corresponding to the line X in FIG. 1 following gate spacer formation, bottom dielectric insulator layer (BDI) formation, and middle dielectric insulator layer (MDI) formation, according to an illustrative embodiment.

FIG. 6B depicts a second cross-sectional view corresponding to the line Y1 in FIG. 1 following gate spacer formation, BDI formation, and MDI formation, according to an illustrative embodiment.

FIG. 6C depicts a third cross-sectional view corresponding to the line Y2 in FIG. 1 following gate spacer formation, BDI formation, and MDI formation, according to an illustrative embodiment.

FIG. 7A depicts a first cross-sectional view corresponding to the line X in FIG. 1 following nanosheet stack recessing, removal of exposed portions of the BDI layer and the underlying semiconductor layer, inner spacer formation, and placeholder cavity formation according to an illustrative embodiment.

FIG. 7B depicts a second cross-sectional view corresponding to the line Y1 in FIG. 1 following nanosheet stack recessing, removal of exposed portions of the BDI layer and the underlying semiconductor layer, inner spacer formation, and placeholder cavity formation according to an illustrative embodiment.

FIG. 7C depicts a third cross-sectional view corresponding to the line Y2 in FIG. 1 following nanosheet stack recessing, removal of exposed portions of the BDI layer and the underlying semiconductor layer, inner spacer formation, and placeholder cavity formation according to an illustrative embodiment.

FIG. 8A depicts a first cross-sectional view corresponding to the line X in FIG. 1 following placeholder formation, epitaxial source/drain region formation, inter-layer dielectric (ILD) formation, and chemical mechanical planarization (CMP), according to an illustrative embodiment.

FIG. 8B depicts a second cross-sectional view corresponding to the line Y1 in FIG. 1 following placeholder formation, epitaxial source/drain region formation, ILD formation, and CMP, according to an illustrative embodiment.

FIG. 8C depicts a third cross-sectional view corresponding to the line Y2 in FIG. 1 following placeholder formation, epitaxial source/drain region formation, ILD formation, and CMP, according to an illustrative embodiment.

FIG. 9 depicts the top view of a semiconductor structure with lines X, Y1 and Y2 on which the cross-sectional views of FIGS. 10A-19C are based, according to an illustrative embodiment.

FIG. 10A depicts a first cross-sectional view corresponding to the line X in FIG. 9 following dummy gate removal, sacrificial semiconductor layer removal, and replacement metal gate (RMG) formation, according to an illustrative embodiment.

FIG. 10B depicts a second cross-sectional view corresponding to the line Y1 in FIG. 9 following dummy gate removal, sacrificial semiconductor layer removal, and RMG formation, according to an illustrative embodiment.

FIG. 10C depicts a third cross-sectional view corresponding to the line Y2 in FIG. 9 following dummy gate removal, sacrificial semiconductor layer removal, and RMG formation, according to an illustrative embodiment.

FIG. 11A depicts a first cross-sectional view corresponding to the line X in FIG. 9 following deep gate cut and shallow gate cut formation, according to an illustrative embodiment.

FIG. 11B depicts a second cross-sectional view corresponding to the line Y1 in FIG. 9 following deep gate cut and shallow gate cut formation, according to an illustrative embodiment.

FIG. 11C depicts a third cross-sectional view corresponding to the line Y2 in FIG. 9 following deep gate cut and shallow gate cut formation, according to an illustrative embodiment.

FIG. 12A depicts a first cross-sectional view corresponding to the line X in FIG. 9 following middle-of-line (MOL) contact formation, back-end-of-line (BEOL) interconnect formation and carrier wafer bonding, according to an illustrative embodiment.

FIG. 12B depicts a second cross-sectional view corresponding to the line Y1 in FIG. 9 following MOL contact formation, BEOL interconnect formation and carrier wafer bonding, according to an illustrative embodiment.

FIG. 12C depicts a third cross-sectional view corresponding to the line Y2 in FIG. 9 following MOL contact formation, BEOL interconnect formation and carrier wafer bonding, according to an illustrative embodiment.

FIG. 13A depicts a first cross-sectional view corresponding to the line X in FIG. 9 following wafer flipping and semiconductor substrate removal, according to an illustrative embodiment.

FIG. 13B depicts a second cross-sectional view corresponding to the line Y1 in FIG. 9 following wafer flipping and semiconductor substrate removal, according to an illustrative embodiment.

FIG. 13C depicts a third cross-sectional view corresponding to the line Y2 in FIG. 9 following wafer flipping and semiconductor substrate removal, according to an illustrative embodiment.

FIG. 14A depicts a first cross-sectional view corresponding to the line X in FIG. 9 following etch stop and selective semiconductor layer removal, according to an illustrative embodiment.

FIG. 14B depicts a second cross-sectional view corresponding to the line Y1 in FIG. 9 following etch stop and selective semiconductor layer removal, according to an illustrative embodiment.

FIG. 14C depicts a third cross-sectional view corresponding to the line Y2 in FIG. 9 following etch stop and selective semiconductor layer removal, according to an illustrative embodiment.

FIG. 15A depicts a first cross-sectional view corresponding to the line X in FIG. 9 following backside ILD layer formation, planarization, and backside ILD layer patterning for backside contacts, according to an illustrative embodiment.

FIG. 15B depicts a second cross-sectional view corresponding to the line Y1 in FIG. 12 following backside ILD layer formation, planarization, and backside ILD layer patterning for backside contacts, according to an illustrative embodiment.

FIG. 15C depicts a third cross-sectional view corresponding to the line Y2 in FIG. 9 following backside ILD layer formation, planarization, and backside ILD layer patterning for backside contacts, according to an illustrative embodiment.

FIG. 16A depicts a first cross-sectional view corresponding to the line X in FIG. 9 following sacrificial placeholder removal and backside contact formation, according to an illustrative embodiment.

FIG. 16B depicts a second cross-sectional view corresponding to the line Y1 in FIG. 9 following backside contact formation, according to an illustrative embodiment.

FIG. 16C depicts a third cross-sectional view corresponding to the line Y2 in FIG. 9 following backside contact formation, according to an illustrative embodiment.

FIG. 17A depicts a first cross-sectional view corresponding to the line X in FIG. 9 following backside interconnect formation, according to an illustrative embodiment.

FIG. 17B depicts a second cross-sectional view corresponding to the line Y1 in FIG. 9 following backside interconnect formation, according to an illustrative embodiment.

FIG. 17C depicts a third cross-sectional view corresponding to the line Y2 in FIG. 9 following backside interconnect formation, according to an illustrative embodiment.

FIG. 18A depicts a first cross-sectional view corresponding to the line Y1 in FIG. 9 of another arrangement of the semiconductor structure shown in FIG. 1, according to an illustrative embodiment.

FIG. 18B depicts a first cross-sectional view corresponding to the line Y2 in FIG. 9 of another arrangement of the semiconductor structure shown in FIG. 1, according to an illustrative embodiment.

FIG. 19A depicts a first cross-sectional view corresponding to the line Y1 in FIG. 9 of yet another arrangement of the semiconductor structure shown in FIG. 1, according to an illustrative embodiment.

FIG. 19B depicts a first cross-sectional view corresponding to the line Y2 in FIG. 9 of yet another arrangement of the semiconductor structure shown in FIG. 1, according to an illustrative embodiment.

### DETAILED DESCRIPTION

Illustrative embodiments are described herein in the context of illustrative methods for stacked device structures with split device layers, along with illustrative apparatus, systems and devices formed using such methods. However, it is to be understood that embodiments described herein are not limited to the illustrative methods, apparatus, systems, and devices but instead are more broadly applicable to other suitable methods, apparatus, systems, and devices.

It is noted that the term “layer characteristics” as used herein is intended to be broadly construed so as to encompass, for example, a number and/or a width of channel layers.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A FET is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in fin field-effect transistors (FinFET). Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves selectively removing sacrificial layers, which may be formed of silicon germanium (SiGe), between sheets of channel material, which may be formed of silicon (Si).

For continued scaling (for example, to 2.5 nm and beyond), next-generation stacked FET (SFET) devices may be used. Next-generation SFET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation SFET structures provide improved track height scaling, leading to structural gains (for example, such as 30-40% structural gains for different types of devices, such as logic devices, static random-access memory (SRAM) devices, etc.). In next-generation SFET structures, n-type, and p-type nanowires or nanosheets are stacked on each other, eliminating n-to-p separation bottlenecks, and reducing the device area footprint. There is, however, a continued desire for further scaling and reducing the size of FETs.

As discussed above, various techniques may be used to reduce the size of FETs, including using fin-shaped channels in FinFET devices, using stacked nanosheet channels formed over a semiconductor substrate, and using next-generation SFET devices.

Although embodiments described herein are discussed in connection with nanosheet stacks, the embodiments are not necessarily limited thereto, and may similarly apply to nanowire stacks.

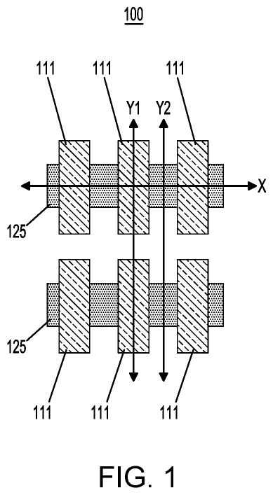

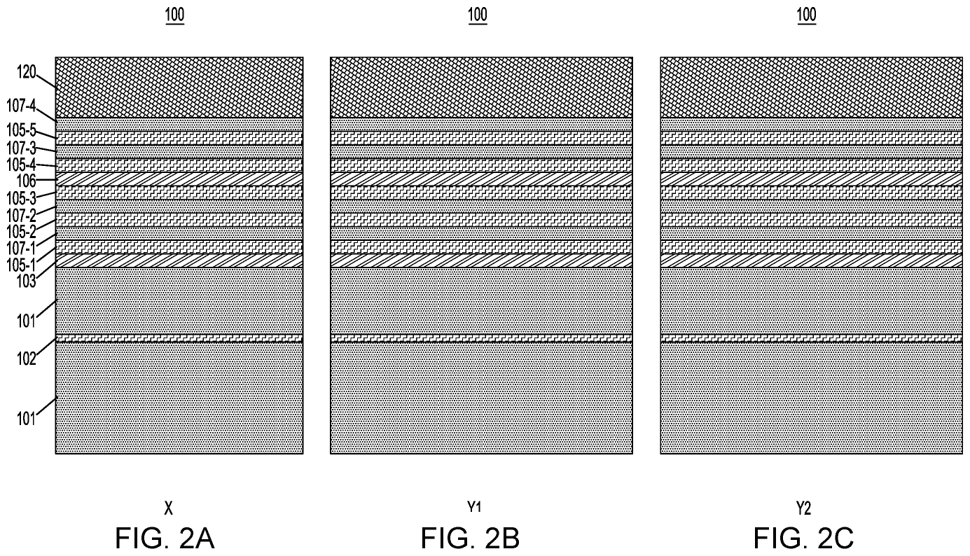

FIG. 1 depicts a top view of a semiconductor structure with lines X, Y1, and Y2 on which the cross-sectional views of FIGS. 2A-8C are based, according to an illustrative embodiment. Referring to FIG. 1 and to the cross-sectional views in FIGS. 2A, 2B and 2C, which respectively correspond to the lines X, Y1, and Y2 in FIG. 1, a semiconductor structure 100 includes a stacked structure of sacrificial layers 105-1, 105-2, 105-3, 105-4, and 105-5 (collectively “sacrificial layers 105”) and channel layers 107-1, 107-2, 107-3, and 107-4 (collectively “channel layers 107”). In an illustrative embodiment, the sacrificial layers 105 comprise SiGe and the channel layers 107 comprise silicone. In illustrative embodiments, the sacrificial layers 105 comprise a germanium concentration of about 25% (for example, SiGe25), but the embodiments are not necessarily limited to SiGe25 for the sacrificial layers 105.

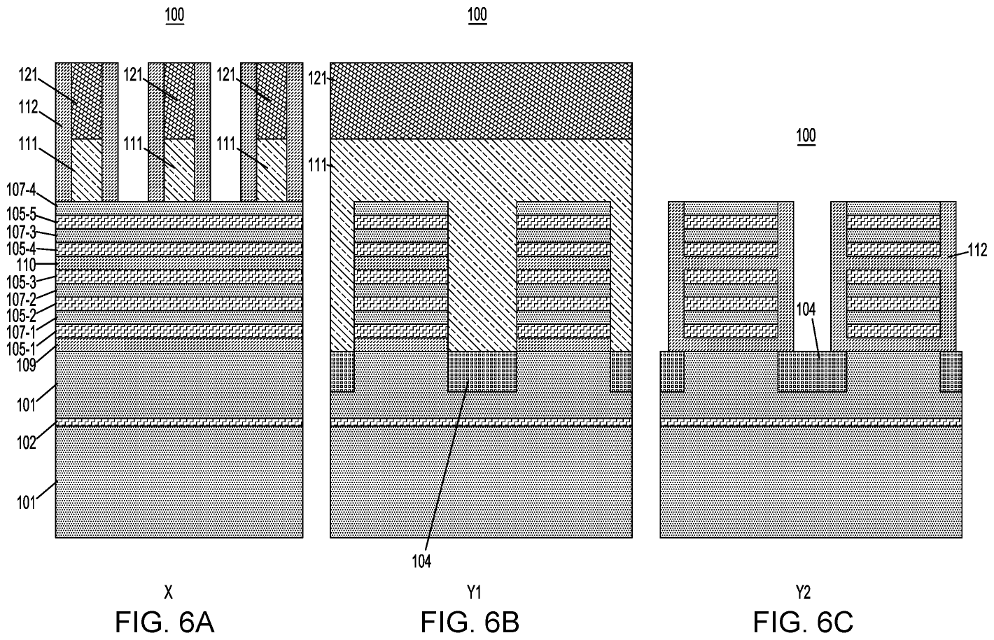

The stacked structure also includes two additional sacrificial layers 103 and 106. The sacrificial layers 103 and 106 can be formed of SiGe with a different concentration of germanium than that of the sacrificial layers 105. For example, the additional sacrificial layers 103 and 106 can have, but are not necessarily limited to, a germanium concentration of about 55% (for example, SiGe55). As explained in more detail herein, the additional sacrificial layers 103 and 105 have a different concentration of germanium than the sacrificial layers 105 so that remaining portions of the additional sacrificial layer 103 can be selectively etched and removed with respect to sacrificial layers 105 when forming bottom dielectric isolation (BDI) and middle dielectric isolation (MDI) layers (see, for example, FIGS. 6A-6C including BDI layers 109 and MDI layers 110).

While five sacrificial layers 105 and four channel layers 107 are shown, embodiments described herein are not necessarily limited to the shown number of sacrificial layers 105 and channel layers 107, and there may be more or less layers in the same alternating configuration depending on design constraints. The sacrificial layers 105, as described further herein, are eventually removed, and replaced by gate structures.

The sacrificial layers 103, 105, and 106 and the channel layers 107 are epitaxially grown on a semiconductor substrate 101 (also referred to herein as semiconductor layer 101). The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The semiconductor substrate 101 may be formed of any suitable semiconductor structure, including various silicon-containing materials including but not limited to Si, SiGe, silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), and zinc selenide (ZnSe).

As used herein, “frontside or “first side” refers to a side on top of the semiconductor substrate 101 and/or in front of, on top of or in an upward direction from the stacked gate and channel layers of the transistors in the orientation shown in the cross-sectional figures. As used herein, “backside” or “second side” refers to a side below the semiconductor substrate 101 and/or behind, below or in a downward direction from the stacked gate and channel layers of the transistors in the orientation shown in the cross-sectional figures (for example, opposite the “frontside”).

An etch stop layer 102 is formed in the semiconductor substrate 101. The etch stop layer 102 may comprise a buried oxide (BOX) layer or SiGe, or another suitable material such as a III-V semiconductor epitaxial layer. In some embodiments, the etch stop layer 102 can have a height in the range of 10 to 30 nm.

A hardmask (HM) layer 120 is formed on the topmost channel layer 107-4 using any conventional deposition technique such as by physical vapor deposition (PVD), atomic layer deposition (ALD), chemical vapor deposition (CVD), etc., followed by a planarization step such as a CMP process. The HM layer 120 can be formed of any suitable material such as, for example, amorphous silicon, or another suitable material.

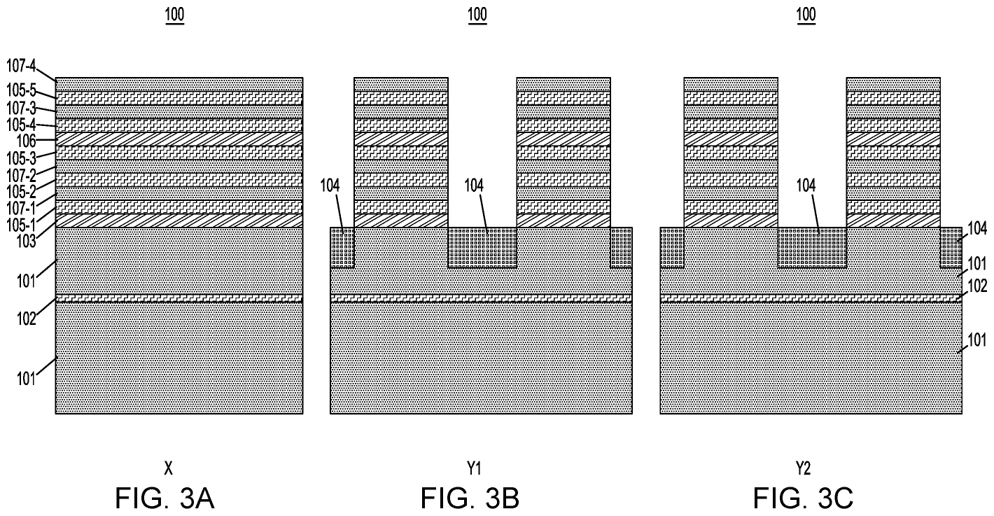

Referring to FIGS. 3A-3C, portions of the nanosheet stacks comprising the sacrificial layers 105, 106 and the channel layers 107 are removed, and portions of the additional sacrificial layer 103 and of the semiconductor layer 101 are recessed. Isolation regions 104 (for example, shallow trench isolation (STI)) regions are formed between the remaining nanosheet stacks, and the remaining portions of the additional sacrificial layers 103, 106, and the semiconductor layer 101.

As can be seen in FIGS. 3B and 3C, portions of the semiconductor layer 101 are removed, and portions of the semiconductor layer 101 are recessed to a lower height. Isolation regions 104 comprising dielectric material fill in the recessed portions of the semiconductor layer 101 and the vacant areas left by the removal of the portions of the additional sacrificial layer 103 and the semiconductor layer 101. The dielectric material may comprise, for example, silicon nitride (SIN), silicon oxynitride (SiON), silicon-carbon-nitride (SiCN), boron nitride (BN), silicon boron nitride (SiBN), silicoboron carbonitride (SiBCN), silicon oxycarbonitride (SiOCN) and combinations thereof, and is deposited using deposition techniques such as, for example, CVD, plasma enhanced CVD (PECVD), radio-frequency CVD (RFCVD), PVD, ALD, molecular beam deposition (MBD), pulsed laser deposition (PLD), and/or liquid source misted chemical deposition (LSMCD).

In some embodiments, the semiconductor structure 100 can correspond to a multi-stacked transistor structure. In this context and elsewhere herein the term “multi-stacked transistor structure” is intended to be broadly construed so as to encompass, for example, a transistor structure having multiple stacked structures, possibly formed as part of the same process and/or materials. For example, in FIGS. 3B and 3C, two separate stacks of layers are shown, which include sacrificial layers 103, 105, and 106, and stacked channel layers 107.

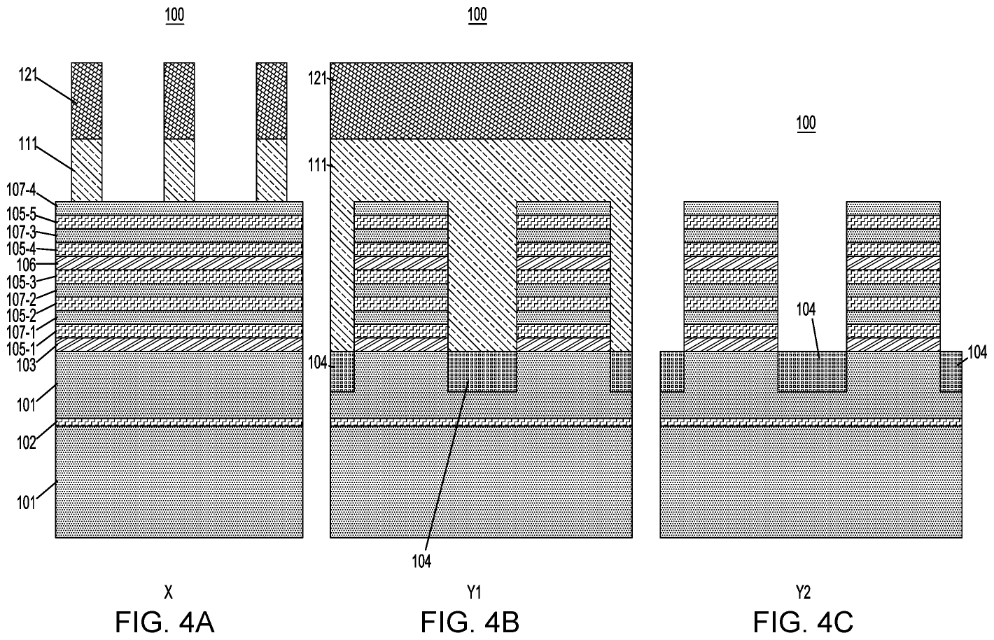

Referring to FIGS. 4A-4C, dummy gate portions 111 are formed on the uppermost channel layers 107-4 and around the stacked nanosheet configurations of the sacrificial layers 105 and channel layers 107. The dummy gate portions 111 include, but are not necessarily limited to, an amorphous silicon (a-Si) layer. The dummy gate portions 111 are deposited using deposition techniques such as, for example, CVD, PECVD, RFCVD, PVD, ALD, MBD, PLD, LSMCD, sputtering and/or plating, followed by a planarization process, such as, CMP, and lithography and etching steps to remove excess dummy gate material, and pattern the deposited layer. Gate HM layers 121 are formed on the dummy gate portions 111. The gate HM layers 121 comprise, for example, a nitride such as SiN or other nitride material.

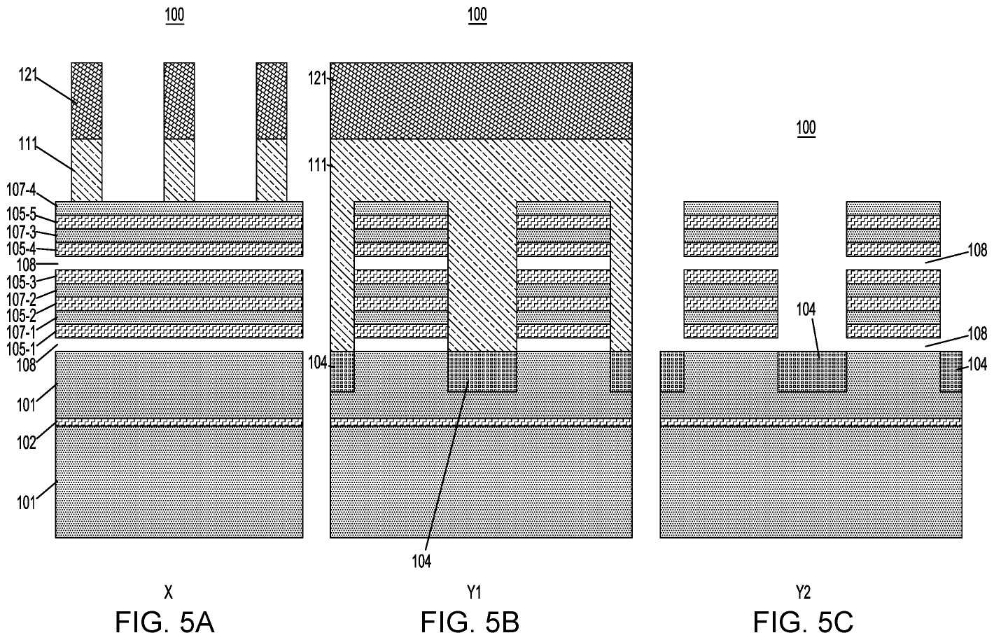

Referring to FIGS. 5A-5C, the remaining portions of the additional sacrificial layers 103 and 106 and the remaining portions of the semiconductor layer 101 are removed using, for example, an aqueous solution containing ammonium hydroxide (NH₄OH) and hydrogen peroxide (H₂O₂) or a gas containing hydrogen fluoride (HF) to selectively etch the portions of the additional sacrificial layers 103 and 106 with respect to the portions of the semiconductor layer 101, the sacrificial layers 105 and the channel layers 107. The selective etching removes the remaining portions of the additional sacrificial layers 103 and 106 to form vacant areas 108 where the BDI layers 109 and MDI layers 110 will be formed.

Referring to FIGS. 6A-6C, following the removal of the remaining portions of the additional sacrificial layer 103 and 106, dielectric material is deposited in place of the remaining portions of the additional sacrificial layer 103 and 106 using deposition techniques such as, for example, CVD, PECVD, RFCVD, PVD, ALD, MBD, PLD, and/or LSMCD, followed by an etch back to form the BDI layers 109 and MDI layers 110 in the vacant areas 108, as shown. The BDI layers 109 and MDI layers 110 may comprise, for example, silicon oxide (SiOx) (where x is for example, 2, 1.99 or 2.01), silicon oxycarbide (SiOC), SiN, SION, SiCN, BN, SiBCN, SiOCN or some other dielectric.

Referring to FIG. 6A, gate spacers 112 are formed on sides of the HM layers 121 and dummy gate portions 111 by one or more of the deposition techniques noted in connection with deposition of the dummy gate material. The spacer material can comprise for example, one or more dielectrics, including, but not necessarily limited to, SiN, SiON, SiOC, SiCN, BN, SiBN, SiBCN, SiOCN, SiOx, and combinations thereof. According to an embodiment, the HM layers 121 and gate spacers 112 can be the same material or different materials. The gate spacers 112 can be formed by any suitable techniques such as deposition followed by directional etching. Deposition may include but is not limited to, ALD or CVD. Directional etching may include but is not limited to, reactive ion etching (RIE).

Referring to FIG. 6C, gate spacers 112 are also formed on sides of the sacrificial layers 105, the channel layers 107, the BDI layers 109, and the MDI layers 110, as shown, in a similar manner as described above, for example.

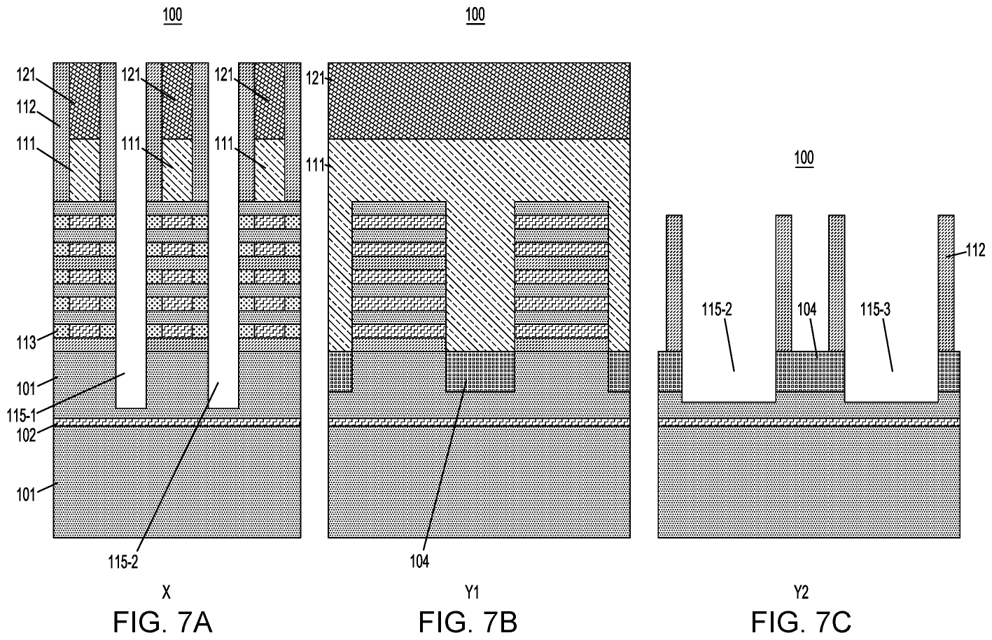

Referring to FIGS. 7A-7C, exposed portions of the stacked sacrificial layers 105 and the channel layers 107, which are not under the gate HM layers 121, the gate spacers 112, and the dummy gate portions 111, are removed using, for example, an etching process, such as RIE, where the gate HM layers 121, the gate spacers 112, and the dummy gate portions 111 are used as a mask.

As can be seen in FIG. 7A, the portions of the stacked structures of sacrificial layers 105 and the channel layers 107 under the gate HM layers 121, the gate spacers 112 and under the dummy gate portions 111 remain after the etching process, and portions of the sacrificial layers 105 and the channel layers 107 in areas that correspond to where source/drain regions will be formed are removed. Portions of the top surface of the BDI layer 109 on sides of the stacked structures of the sacrificial layers 105 and the channel layers 107 are exposed. Due to, for example, germanium in the sacrificial layers 105, lateral etching of the sacrificial layers 105 can be performed selective to the channel layers 107, such that the side portions of the sacrificial layers 105 can be removed to create vacant areas to be filled in by inner spacers 113. The material of the inner spacers 113 can comprise, but is not necessarily limited to, a nitride, such as, SiN, SiON, SiCN, BN, SiBN, SiBCN or SiOCN. Gate spacers 112 are positioned on the nanosheet stacks on opposite lateral sides of the dummy gate portions 111. In an illustrative embodiment, the gate spacers 112 are formed from the same or similar material to that of the inner spacers 113. Like the gate spacers 112, the inner spacers 113 can be formed by any suitable techniques such as deposition followed by directional etching.

In accordance with an illustrative embodiment, exposed side surfaces of the channel layers 107, which comprise, for example, silicon, are exposed to arsine, which poisons the side surfaces with arsenic. As a result, in a subsequent epitaxial growth process as described further herein, epitaxial nucleation from the exposed side surfaces of the channel layers 107 is delayed. The surfaces have a <110> orientation. Multiple nucleation surfaces formed by each of the channel layers 107 results in stacking faults during source/drain epitaxial growth. Poisoning the side surfaces with arsenic prevents or delays epitaxial growth from the side surfaces such that the stacking faults are prevented or reduced. As explained further herein, the embodiments provide for bottom-up growth of source/drain regions to limit or prevent the stacking faults and the exposure of the side surfaces of the channel layers 107 to arsine is optional.

Exposed portions of the BDI layer 109 between the stacked structures of the sacrificial layers 105 and the channel layers 107 are removed in a first removal process. Following removal of the exposed portions of the BDI layer 109 between the stacked structures of sacrificial layers 105 and the channel layers 107, underlying portions of the semiconductor layer 101 are removed, such that portions of the semiconductor layer 101 are recessed to create trenches 115-1, 115-2 and 115-3 (collectively “trenches 115”) in the semiconductor layer 101. The semiconductor layer 101 can be etched using, for example, Tetramethyl ammonium hydroxide (TMAH) solution, to selectively remove SiGe having a relatively higher percentage of germanium, or CF₄ gas to selectively remove SiGe having a relatively lower percentage of germanium. As can be seen, the exposed portions of the semiconductor layer 101 are recessed below the bottom surfaces of the remaining portions of the BDI layer 109 and below the isolation regions 104.

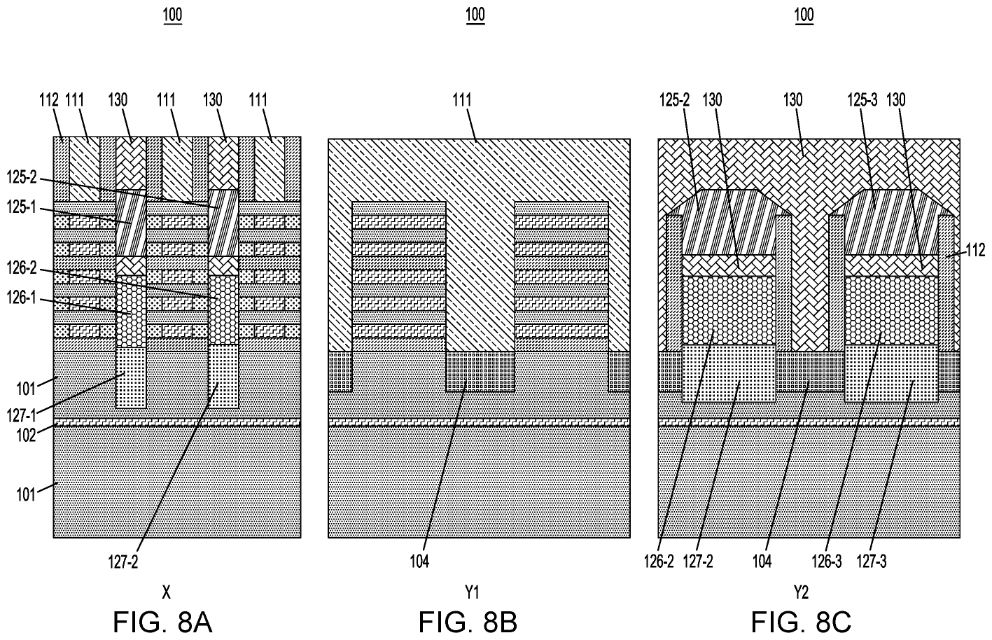

Referring to FIGS. 8A-8C, the trenches 115 are filled with sacrificial materials to form sacrificial placeholders 127-1, 127-2, and 127-3 (collectively “sacrificial placeholders 127”). Bottom source/drain regions 126-1, 126-2, and 126-3 (collectively “bottom source/drain regions 126”), and top source/drain regions 125-1, 125-2, and 125-3 (collectively “top source/drain regions 125”), and an inter-layer dielectric (ILD) layer 130 are formed. In illustrative embodiments, the sacrificial placeholders 127 can comprise, for example, SiGe, III-V semiconductor material or other semiconductor material. The sacrificial placeholders 127, the bottom source/drain regions 126, and the top source/drain regions 125 can be epitaxially grown in a bottom-up epitaxial growth process. For example, the sacrificial placeholders 127 can be grown from the exposed portions of the semiconductor layer 101, and the bottom source/drain regions 126 can be epitaxially grown from the exposed surfaces of their corresponding sacrificial placeholders 127.

The process is referred to as a bottom-up epitaxial growth process because epitaxial growth occurs at a faster rate from the bottom surfaces of the portions of the semiconductor layer 101 in the trenches 115 than from the side surfaces of the channel layers 107. For example, epitaxial material from the <100> orientation surfaces of the semiconductor layer 101 nucleates faster and has a faster growth rate than from the <110> orientation surfaces of the channel layers 107. This difference in growth is increased when the side surfaces of the channel layers 107 are exposed to arsine.

As can be seen, the bottom portions of the sacrificial placeholders 127 are disposed in and fill the trenches 115, and the bottom portions of the bottom source/drain regions 126 are positioned above the sacrificial placeholders 127 and between the stacked structure of sacrificial layers 105 and channel layers 107. The isolation regions 104 are disposed around one or more sides of the sacrificial placeholders 127. Side surfaces of respective ones of the channel layers 107 contact a side surface of at least one adjacent bottom source/drain region 126 or top source/drain region 125. The top surfaces of the top source/drain regions 125 are above the top surfaces of uppermost ones of the channel layers 107.

According to a non-limiting embodiment, the conditions of the epitaxial growth process for the source/drain regions 125 and 126 are, for example, RTCVD epitaxial growth using SiH₄, SiH₂Cl₂, GeH₄, CH₃SiH₃, B₂H₆, PF₃, and/or H₂ gases with temperature and pressure ranges of about 450° C. to about 800° C., and about 5 Torr—about 300 Torr. In the case of n-type FETS (nFETs), the source/drain regions 125 and 126 can comprise silicon doped with n-type dopants including, for example, phosphorus (P), arsenic (As) and antimony (Sb). In the case of p-type FETS (pFETs), the source/drain regions 125 and 126 can comprise silicon doped with n-type dopants including, for example, boron (B), boron fluoride (BF₂), gallium (Ga), indium (In), and thallium (TI).

The ILD layer 130 is deposited to fill in portions on and around the source/drain regions 125 and 126. The ILD layer 130 is deposited using deposition techniques such as, for example, CVD, PECVD, RFCVD, PVD, ALD, MBD, PLD, and/or LSMCD, followed by a planarization process, such as, CMP to remove excess portions of the ILD layer 130 deposited on top of the gate HM layers 121 and gate spacers 112, and to remove the gate HM layers 121 and portions of the gate spacers 112 to expose the dummy gate portions 111. The ILD layer 130 may comprise, for example, SiOx, SiOC, SiOCN or some other dielectric.

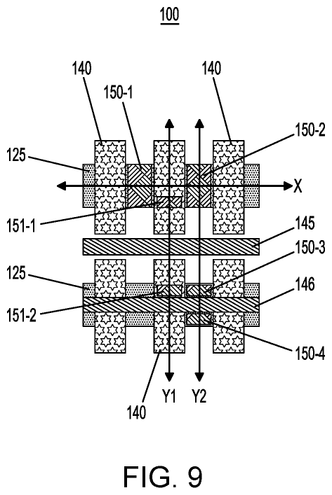

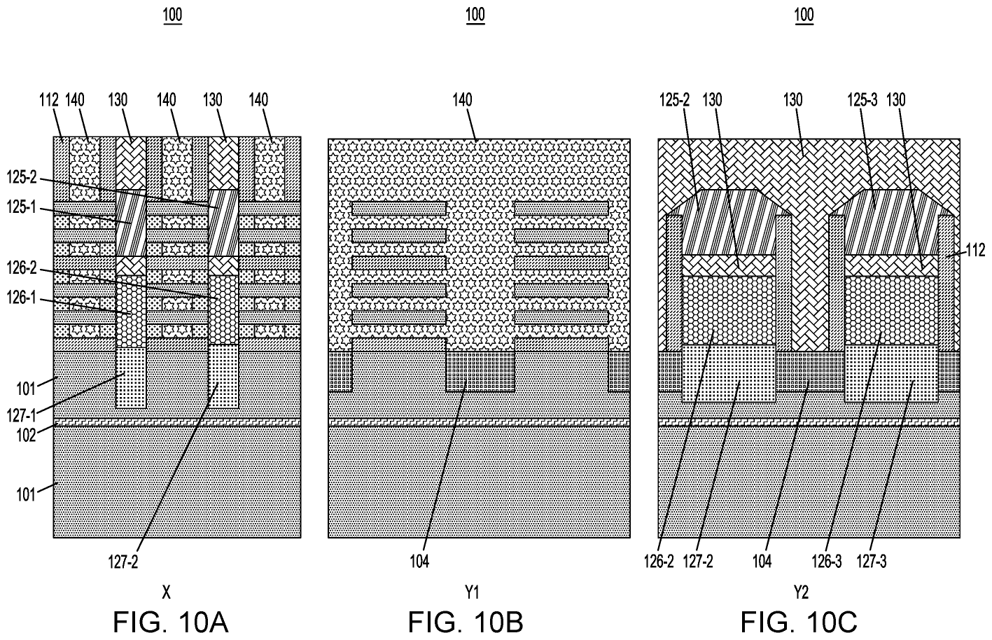

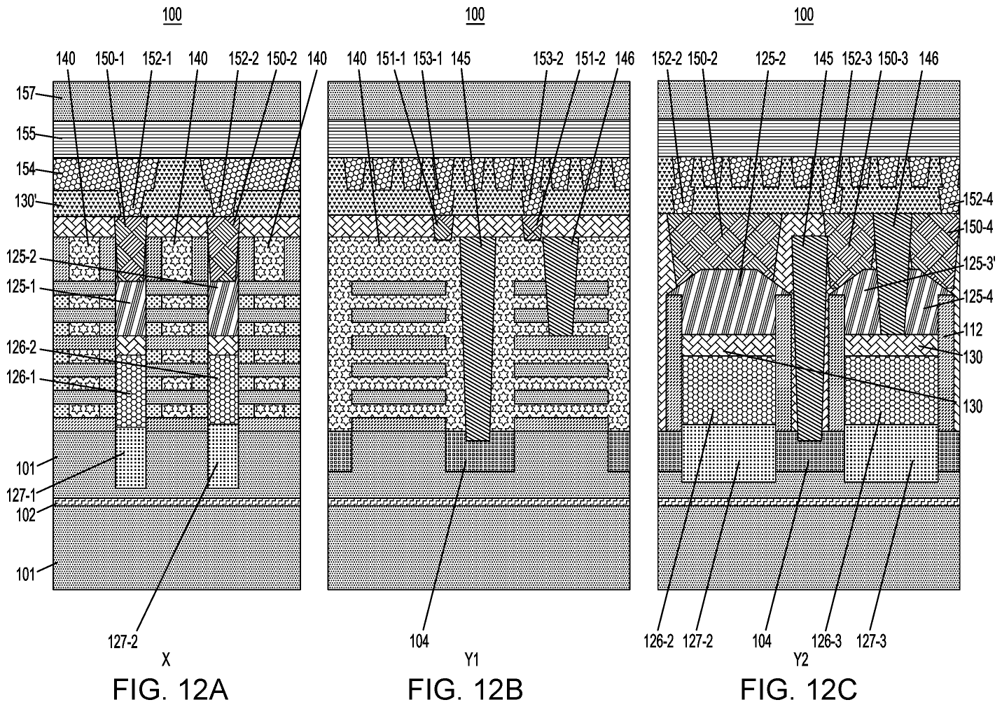

FIG. 9 depicts a top view of the semiconductor structure 100 with lines X, Y1, and Y2 on which the cross-sectional views of FIGS. 10A-17C are based. FIG. 9 illustrates gate regions 140, a gate cut portion 145 and 146, frontside source/drain contacts 150-1, 150-2, 150-3, 150-4 (collectively “frontside source/drain contacts 150”) and gate contacts 151-1 and 151-2 (collectively “gate contacts 151”), which are described in more detail herein in connection with, for example, FIGS. 12A-12C.

Referring to FIGS. 10A-10C, the dummy gate portions 111 and the sacrificial layers 105 are selectively removed to create vacant areas, and gate regions 140 are formed in the vacant areas. For example, the dummy gate portions 111 can be selectively removed using hot ammonia to remove a-Si, and the sacrificial layers 105 can be selectively removed with respect to the channel layers 107 using, for example, a dry HCl etch.

Following removal of the dummy gate portions 111 and the sacrificial layers 105, the channel layers 107 are suspended, and the gate regions 140, including, for example, gate and dielectric portions are formed in the vacant portions left by removal of the dummy gate portions 111 and the sacrificial layers 105. In illustrative embodiments, each gate region 140 includes a gate dielectric layer such as, for example, a high-K dielectric layer including, but not necessarily limited to, HfO₂ (hafnium oxide), ZrO₂ (zirconium dioxide), hafnium zirconium oxide, Al₂O₃ (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate.

According to an embodiment, the gate regions 140 each include a metal gate portion including a work-function metal (WFM) layer, including but not necessarily limited to, for a pFET, titanium nitride (TiN), tantalum nitride (TaN) or ruthenium (Ru), and for an nFET, TiN, titanium aluminum nitride (TiAIN), titanium aluminum carbon nitride (TiAICN), titanium aluminum carbide (TiAIC), tantalum aluminum carbide (TaAIC), tantalum aluminum carbon nitride (TaAICN) or lanthanum (La) doped TiN, TaN, which can be deposited on the gate dielectric layer. The metal gate portions can also each further include a gate metal layer including, but not necessarily limited to, metals, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer. It should be appreciated that various other materials may be used for the metal gate portions as desired.

Part of gate region 140 between the nanosheet stacks comprising the channel layers 107 and the gate regions 140, and between the source/drain regions 125 and 126 is removed down to an isolation region 104, and part of the exposed portion of the isolation region 104 is also removed to form a trench in which dielectric material is deposited to form gate cut portion 145. The part of the gate region 140 is etched using, for example, RIE. The exposed portion of the isolation region 104 is etched using, for example, RIE. The dielectric material of the gate cut portion 145 is deposited using deposition techniques such as, for example, CVD, PECVD, RFCVD, PVD, ALD, MBD, PLD, and/or LSMCD, followed by a planarization process, such as, CMP to remove excess portions of the dielectric material deposited on top of the gate region 140. The dielectric material of the gate cut portion 145 (also referred to as a deep gate cut portion) may comprise, but is not necessarily limited to, SiN, SiC, SION, SiOC, SiCN, BN, SiBN, SiBCN, SIOCN, SiOx or some other dielectric.

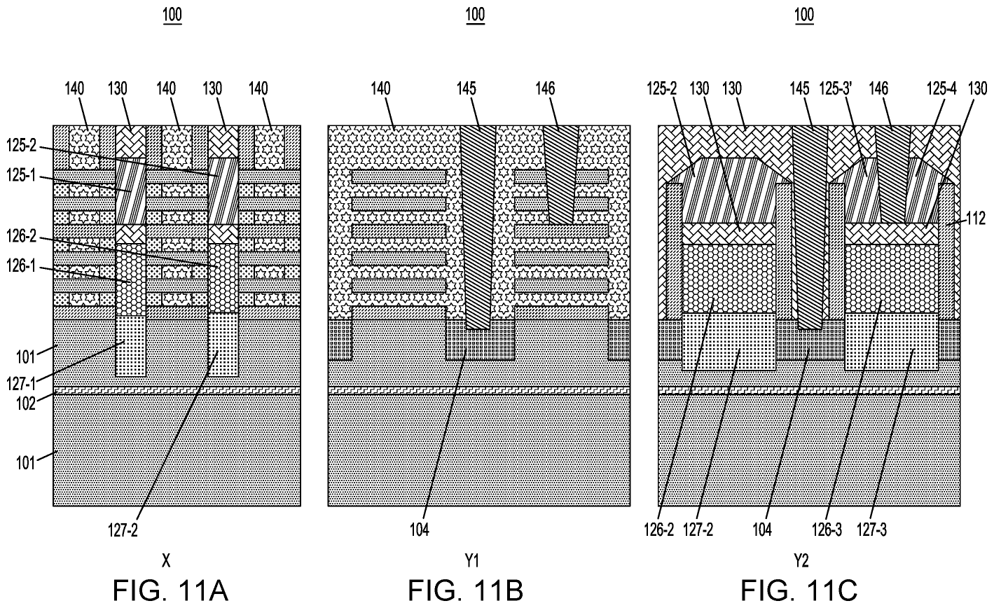

Also, referring to FIG. 11B, part of the gate region 140 and part of the channel layers 107-3 and 107-4 are removed down to the MDI layer 110 to form a trench in which dielectric material is deposited to form the gate cut portion 146 (also referred to as a shallow gate cut portion). The gate cut portion 146 can be formed of similar materials and by using similar techniques as described with respect to gate cut portion 145, for example. The gate cut portion 146 divides the top source/drain region 125-3 into two parts, labeled as top source/drain region 125-3′ and top source/drain region 125-4.

Referring to FIGS. 12A-12C, an additional ILD material is deposited to form an additional ILD layer 130′ on top of the ILD layer 130. Then, frontside source/drain contacts 150-1, 150-2, 150-3, and 150-4 are formed in the ILD layers 130 and 130′ to contact the top source/drain regions 125-1, 125-2, 125-3′, and 125-4, respectively. In forming the frontside source/drain contacts 150-1 and 150-2, openings are formed through portions of the ILD layers 130 and 130′. The openings expose portions of the source/drain regions 125 on which the frontside source/drain contacts 150-1, 150-2, 150-3, and 150-4 are to be formed. According to an embodiment, masks are formed on parts of the additional ILD layer 130′, and exposed portions of the ILD layers 130 and 130′ corresponding to where the openings are to be formed are removed using, for example, a dry etching process using a RIE or ion beam etch (IBE) process, a wet chemical etch process or a combination of these etching processes. A dry etch may be performed using a plasma. Such wet or dry etch processes include, for example, IBE by Ar/CHF3 based chemistry.

Metal layers are deposited in the openings to form the frontside source/drain contacts 150-1, 150-2, 150-3, and 150-4. The metal layers comprise, for example, a silicide layer, such as Ni, Ti, NiPt, etc., a metal adhesion layer, such as TiN, and a conductive metal fill layer, such as W, Al, Co, Ru, etc., and can be deposited using, for example, a deposition technique such as CVD, PECVD, RFCVD, PVD, ALD, MBD, PLD, LSMCD, sputtering and/or plating, followed by a planarization process such as, CMP to remove excess portions of the metal layers from on top of the additional ILD layer 130′.

The frontside source/drain contacts 150-1, 150-2, 150-3, and 150-4 contact respective ones of the top source/drain regions 125-1, 125-2, 125-3′, and 125-4. The frontside source/drain contacts 150-1, 150-2, 150-3, and 150-4 extend through the ILD layers 130 and 130′ to land on and contact the corresponding top source/drain regions 125-1, 125-2, 125-3′, and 125-4.

Frontside gate contacts 151-1 and 151-2 are formed through the additional ILD layer 130′ to land on and contact a corresponding gate structure 140 (which may also be referred to as a gate region). The process and materials used for forming the frontside gate contacts 151-1 and 151-2 are similar to those used for forming the frontside source/drain contacts 151-1 and 151-2. Middle-of-line (MOL) metallization layers 154 are formed in the additional ILD layer 130′. Vias 152-1, 152-2, 152-3, and 152-4 extending from the MOL metallization layers 154 to the frontside source/drain contacts 150-1, 150-2, 150-3, and 150-4, respectively, are also formed in the additional ILD layer 130′. Vias 153-1 and 153-2 extending from the MOL metallization layers 154 to the frontside gate contacts 151-1 and 151-1, respectively, are further formed in the additional ILD layer 130′. The process and materials used for forming the MOL metallization layers 154 and the vias 152-1, 152-2, 152-3, and 152-4, 153-1, and 153-2 are similar to those used for forming the frontside source/drain contacts 150-1, 150-2, 150-3, and 150-4, and the frontside gate contacts 151-1 and 151-2.

Frontside BEOL interconnects 155 are formed on the additional ILD layer 130′ including the MOL metallization layers 154. As can be seen, the MOL metallization layers 154 contact the frontside BEOL interconnects 155. A carrier wafer 157 is bonded to the frontside BEOL interconnects 155. The frontside BEOL interconnects 155 include various BEOL interconnect structures which may electrically connect to the MOL metallization layers 154. The carrier wafer 157 may be formed of materials similar to that of the semiconductor layer 101 and may be formed over the frontside BEOL interconnects 155 using a wafer bonding process, such as dielectric-to-dielectric bonding.

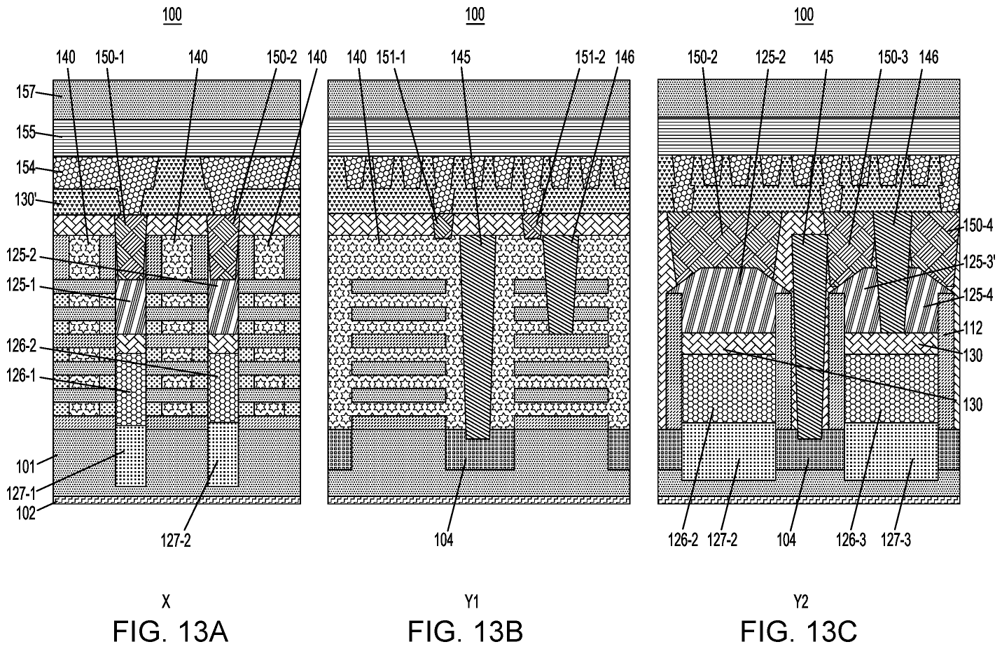

Referring to FIGS. 13A-13C, using the carrier wafer 157, the semiconductor structure 100 may be “flipped” (for example, rotated 180 degrees) so that the structure is inverted. In addition, the semiconductor layer 101 is removed from the backside of the semiconductor structure 100 stopping at the etch stop layer 102. The removal process, which comprises etching of the semiconductor layer 101. For example, the semiconductor layer 101 is selectively etched with an etchant that selectively etches silicon with respect to a material of the etch stop layer 102.

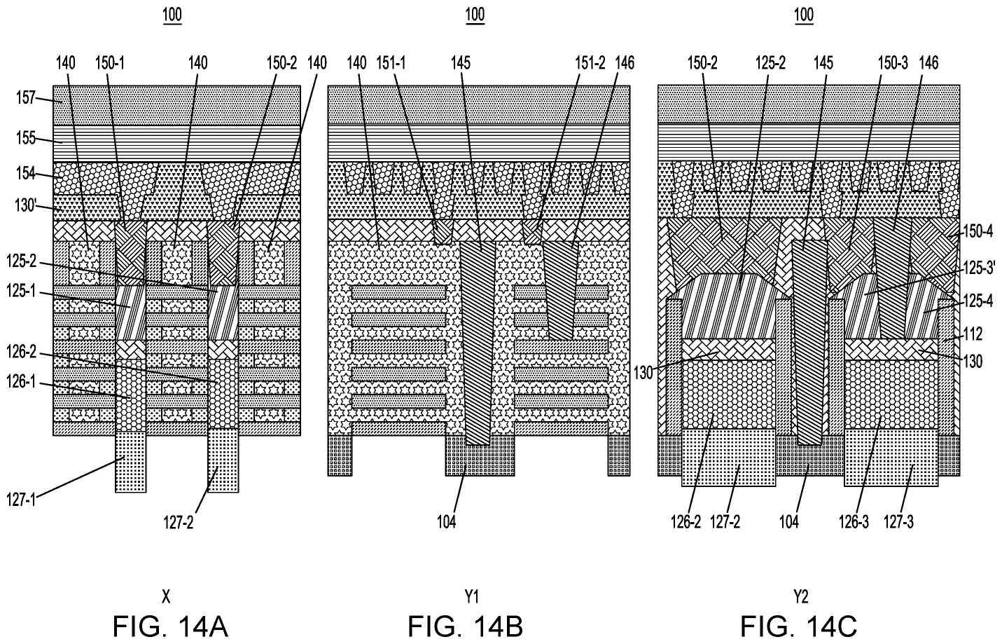

Referring to FIGS. 14A-14C, the etch stop layer 102 and the semiconductor layer 101 are removed. The etching processes for removal of the etch stop layer 102 include, for example, IBE by Ar/CHF3 based chemistry. Etchants for removing the semiconductor layer 101 include, for example, potassium hydroxide (KOH) and TMAH.

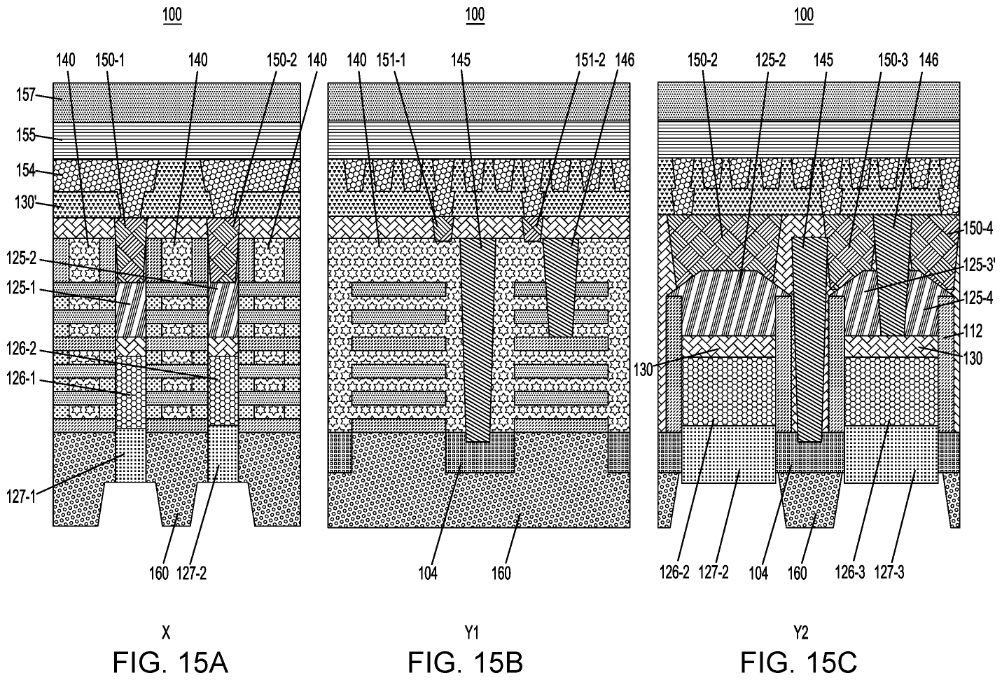

FIGS. 15A-15C show cross-sectional views of the semiconductor structure 100, respectively corresponding to lines X, Y1, and Y2, following formation of a backside ILD layer 160 and backside contact formation, according to an illustrative embodiment. The backside ILD layer 160 can be deposited using deposition techniques such as, for example, CVD, PECVD, RFCVD, PVD, ALD, MBD, PLD, and/or LSMCD, followed by a planarization process, such as, CMP to cause the backside ILD layer 160. The backside ILD layer 160 may comprise, for example, SiOx, SiOC, SiOCN or some other dielectric.

The backside contact formation can include depositing a mask with openings where the backside source/drain contacts are to be formed, and then selectively removing the exposed portions of the backside ILD layer 160 using, for example, a dry etching process using a RIE or IBE process, a wet chemical etching process or a combination of these etching processes. A dry etch may be performed using a plasma. Such wet or dry etch processes include, for example, IBE by Ar/CHF3 based chemistry. The exposed portions of the backside ILD layer 160 can be removed to expose the bottom portions of the sacrificial placeholders 127.

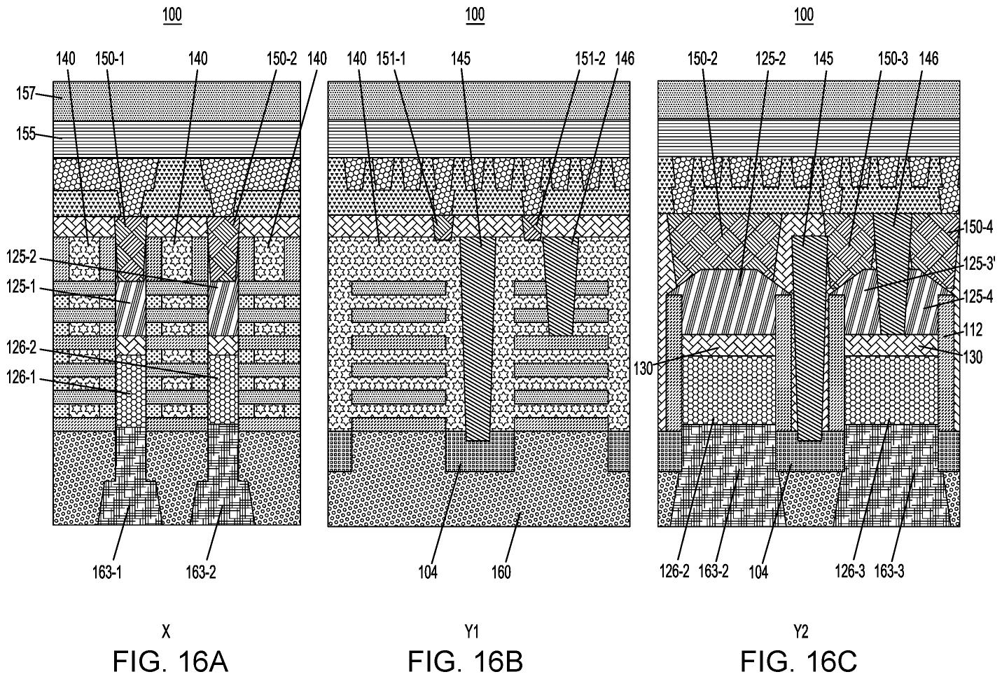

Referring to FIGS. 16A-16C, the sacrificial placeholders 127 can be selectively removed to expose backside portions of the bottom source/drain regions 126. The sacrificial placeholders 127 can be removed using, for example, a selective dry or wet etch process. Backside bottom source/drain contacts 163-1, 163-2, and 163-3 (collectively “backside bottom source/drain contacts 163”) may be formed by fill and planarization of contact material. The contact material of the backside bottom source/drain contacts 163 may be similar to that of the frontside source/drain contacts 150-1, 150-2, 150-3, and 150-4, for example. The backside bottom source/drain contacts 163 contact respective backsides of the source/drain regions 126-1, 126-2, and 126-3.

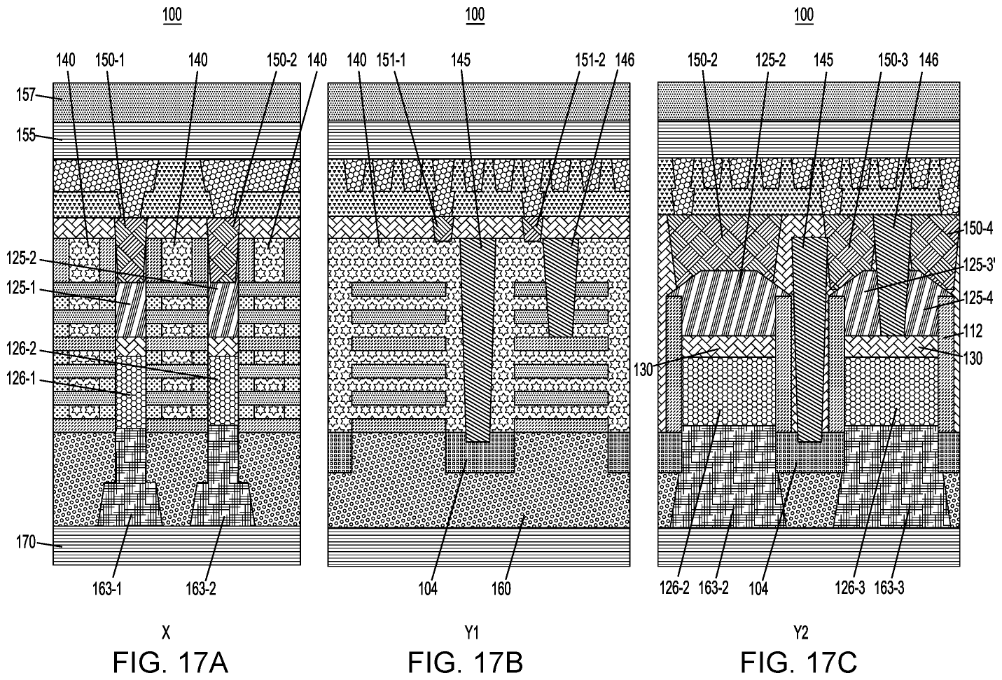

Referring to FIGS. 17A-17C, backside BEOL layers 170 (also referred to herein as backside interconnects) are formed on the backside ILD layer 160 and on the backside bottom source/drain contacts 163. The BEOL layers 170 can include various backside power delivery network structures such as, but not necessarily limited to, interconnects in a power supply path from voltage regulator modules (VRMs) to circuits. The interconnects can comprise, for example, power and ground planes in circuit boards, cables, connectors, and capacitors associated with a power supply. Backside power delivery prevents BEOL routing congestion, resulting in power performance benefits. The backside bottom source/drain contacts 163 are connected to the backside BEOL layers 170. In some embodiments, the backside BEOL layers 170 can alternatively or additionally be used for routing of signals, including power and/or clock signals as non-limiting examples.

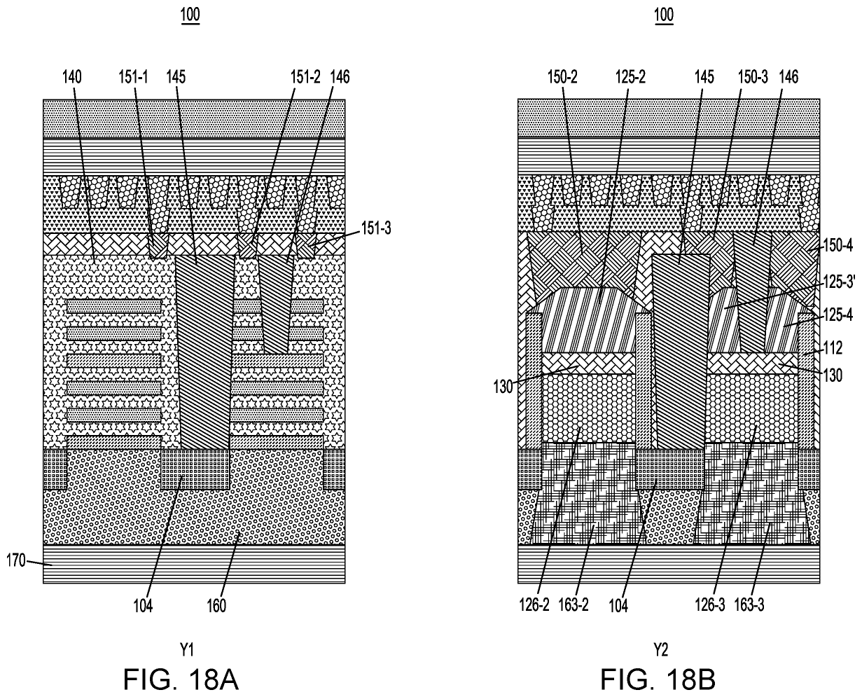

FIGS. 18A and 18B depict respective cross-sectional views corresponding to line Y1 and Y2 in FIG. 9 of another arrangement of the semiconductor structure 100, according to an illustrative embodiment. In this embodiment, the gate cut portion 145 is formed so as to contact the channel layers 107 between the gate cut portions 145 and 146 and isolate the portions of the gate 140 between the gate cut portions 145 and 146 from the other portions of the gate 140. This results in an independent gate top transistor device (corresponding to the channel layers 107 above the MDI layer 110 and between the gate cut portions 145 and 146). In this example, the second gate contact 151-2 contacts the independent gate top transistor device, as shown. Additionally, a top transistor device (corresponding to the channel layers 107 above the MDI layer 110 and on the other side of the gate cut portion 146) and a bottom transistor device (corresponding to the channel layers 107 between the BDI layer 109 and the MDI layer 110, and to the right of the gate cut portion 145) are formed with a shared gate. In this example, a third gate contact 151-3 is formed to contact the portion of the shared gate.

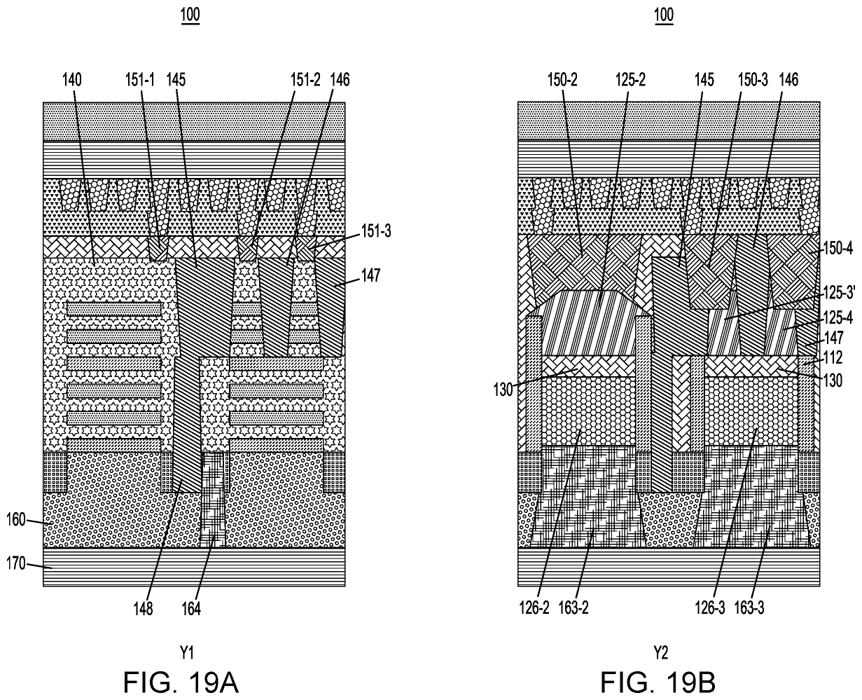

FIGS. 19A and 19B depict respective cross-sectional views corresponding to line Y1 and Y2 in FIG. 9 of yet another arrangement of the semiconductor structure 100, according to an illustrative embodiment. In this embodiment, the gate cut portion 145 is formed in a similar manner as shown in FIGS. 18A-18B except it stops at the MDI layer 110, thereby resulting in an independent gate top transistor device (corresponding to the channel layers 107 above the MDI layer 110 and between the gate cut portions 145 and 146). Similar to FIGS. 18A-18B, a second gate contact 151-2 is formed to contact the independent gate. Additionally, another gate cut portion 147 is formed to create a second independent gate top transistor device (corresponding to the channel layers 107 above the MDI layer 110 and between the gate cut portions 146 and 147), and a third gate contact 151-3 is formed to contact the corresponding gate portion, as shown. A backside gate cut portion 148 is also formed, which contacts the gate cut portion 145, thereby creating an independent bottom gate transistor device (corresponding to the channel layers 107 between the BDI layer 109 and the MDI layer 110, and to the right of the backside gate cut portion 148). A backside gate contact 164 is formed to contact the gate portion corresponding to the bottom gate transistor device, as shown in FIG. 19A.

Semiconductor devices and methods for forming the same in accordance with the above-described techniques can be employed in various applications, hardware, and/or electronic systems. Suitable hardware and systems for implementing embodiments of the present disclosure may include, but are not limited to, personal computers, communication networks, electronic commerce systems, portable communications devices (for example, cell and smart phones), solid-state media storage devices, functional circuitry, etc. Systems and hardware incorporating the semiconductor devices are contemplated embodiments of the present disclosure. Given the teachings provided herein, one of ordinary skill in the art will be able to contemplate other implementations and applications of embodiments of the present disclosure.

In some embodiments, the above-described techniques are used in connection with semiconductor devices that may require or otherwise utilize, for example, CMOSs, MOSFETS, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

Typical, vertical stacking of devices increases design complexity of stacked FET architectures. Greater design flexibility can be achieved by isolating the top devices, to provide greater flexibility for connecting source/drain regions. At least some embodiment described herein can form a stacked FET having at least one split top device over at least one bottom device. Without in any way limiting the scope, interpretation, or application of the claims appearing below, a technical effect of one or more of the example embodiments disclosed herein is improving skew variants (for example, in Engineering Change Order (ECO) cells) by providing flexible source/drain connection layouts. Generally, the term skew variant refers to statistical variations in electrical characteristics, which can lead to various issues, such as timing errors, reduced noise margins, and other performance issues.

In some embodiments, a semiconductor device comprises a multi-stacked transistor structure including a first stacked transistor structure includes a first lower transistor device and a first upper transistor device and a second stacked transistor structure includes a second lower transistor device, a second upper transistor device, and a third upper transistor device.

The second upper transistor device and the third upper transistor device may include a first plurality of channel layers. Each channel layer in the first plurality of channel layers may be surrounded by one or more gate regions and at least one other structure. The at least one other structure may include a first gate cut portion comprising dielectric material disposed between the second upper transistor device and the third upper transistor device. The semiconductor device may include a second gate cut portion comprising dielectric material disposed between the first stacked transistor structure and the second stacked transistor structure. The first lower transistor device, the first upper transistor device, and the second lower transistor device may include a second plurality of channel layers, where each channel layer in the second plurality of channel layers is surrounded by the one or more gate regions. The second stacked transistor structure may include a backside source/drain contact disposed beneath a bottom source/drain region associated with the second lower transistor device. The second stacked transistor structure may include a first frontside source/drain contact for the second upper transistor device and a second frontside source/drain contact for the third upper transistor device. The first frontside source/drain contact and the second frontside source/drain contact may be connected to different signal lines.

In some embodiments, a semiconductor device comprises a first stacked field-effect transistor structure comprising a first lower field-effect transistor device and a first upper field-effect transistor device and a second stacked field-effect transistor structure comprising a second lower field-effect transistor device, a second upper field-effect transistor device, and a third upper field-effect transistor device. The second upper field-effect transistor device and the third upper field-effect transistor device include a plurality of channel layers, each of the channel layers being surrounded by a first gate cut portion (for example, comprising dielectric material) and one or more gate regions.

At least one of the channel layers in the plurality of channel layers may be surrounded by the one or more gate regions on three sides and the first gate cut portion on another side. The first lower field-effect transistor device, the first upper field-effect transistor device, and the second lower field-effect transistor device may include gate-all-around transistor devices. The semiconductor device may include a second gate cut portion comprising dielectric material disposed between the first stacked field-effect transistor and the second stacked field-effect transistor structure. The second stacked field-effect transistor structure may include a backside source/drain contact disposed beneath a bottom source/drain region associated with the second lower field-effect transistor device. The second stacked field-effect transistor structure may include a first frontside source/drain contact for the second upper field-effect transistor device and a second frontside source/drain contact for the third upper field-effect transistor device. The first frontside source/drain contact and the second frontside source/drain contact may be connected to different back-end-of-line signal lines.

In some embodiments, a method includes forming first and second stacked field-effect transistor device structures, where the first stacked field-effect transistor device structure comprises a first plurality of channel layers corresponding to a first upper field-effect transistor device and a first lower field-effect transistor device, and the second stacked field-effect transistor device structure comprises a second plurality of channel layers corresponding to a second upper field-effect transistor device and a second lower field-effect transistor device. The method includes forming a first gate cut portion comprising dielectric material disposed between the first and second stacked field-effect transistor device structures. The method also includes dividing the second upper field-effect transistor device into a third upper field-effect transistor device and a fourth upper field-effect transistor device, wherein the dividing comprises dividing the channels layers corresponding to the second upper field-effect transistor device and forming a second gate cut portion comprising dielectric material between the third upper field-effect transistor device and the fourth upper field-effect transistor device.

The method may include forming a first frontside source/drain contact for the third upper field-effect transistor device, and a second frontside source/drain contact for the fourth upper field-effect transistor device. The method may include forming a gate region that surrounds the channels layers corresponding to the third upper field-effect transistor device, the fourth upper field-effect transistor device, and the first lower field-effect transistor device. The method may include forming a backside source/drain contact disposed beneath a bottom source/drain region associated with the first lower field-effect transistor device. The first frontside source/drain contact and the second frontside source/drain contact may be connected to different back-end-of-line signal lines.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times, and other process parameters, etc., are meant to denote being close or approximate to, but not exactly. For example, the term “approximately” or “substantially” as used herein implies that a small margin of error is present, such as +5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments described herein have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a multi-stacked transistor structure, comprising:
a first stacked transistor structure comprising a first lower transistor device and a first upper transistor device; and
a second stacked transistor structure comprising a second lower transistor device, a second upper transistor device, and a third upper transistor device.

2. The semiconductor device of claim 1, wherein the second upper transistor device and the third upper transistor device comprise a first plurality of channel layers, wherein each channel layer in the first plurality of channel layers is surrounded by one or more gate regions and at least one other structure.

3. The semiconductor device of claim 2, wherein the at least one other structure comprises a first gate cut portion comprising dielectric material disposed between the second upper transistor device and the third upper transistor device.

4. The semiconductor device of claim 3, further comprising:
a second gate cut portion comprising dielectric material disposed between the first stacked transistor structure and the second stacked transistor structure.

5. The semiconductor device of claim 2, wherein the first lower transistor device, the first upper transistor device, and the second lower transistor device comprise a second plurality of channel layers, wherein each channel layer in the second plurality of channel layers is surrounded by the one or more gate regions.

6. The semiconductor device of claim 2, wherein the second stacked transistor structure comprises a backside source/drain contact disposed beneath a bottom source/drain region associated with the second lower transistor device.

7. The semiconductor device of claim 1, wherein the second stacked transistor structure comprises a first frontside source/drain contact for the second upper transistor device and a second frontside source/drain contact for the third upper transistor device.

8. The semiconductor device of claim 7, wherein the first frontside source/drain contact and the second frontside source/drain contact are connected to different signal lines.

9. A semiconductor device comprising:
a first stacked field-effect transistor structure comprising a first lower field-effect transistor device and a first upper field-effect transistor device; and
a second stacked field-effect transistor structure comprising a second lower field-effect transistor device, a second upper field-effect transistor device, and a third upper field-effect transistor device;
wherein the second upper field-effect transistor device and the third upper field-effect transistor device comprise a plurality of channel layers, each of the channel layers being surrounded by a first gate cut portion comprising dielectric material and one or more gate regions.

10. The semiconductor device of claim 9, wherein at least one of the channel layers in the plurality of channel layers is surrounded by the one or more gate regions on three sides and the first gate cut portion on another side.

11. The semiconductor device of claim 9, wherein the first lower field-effect transistor device, the first upper field-effect transistor device, and the second lower field-effect transistor device comprise gate-all-around transistor devices.

12. The semiconductor device of claim 9, further comprising a second gate cut portion comprising dielectric material disposed between the first stacked field-effect transistor and the second stacked field-effect transistor structure.

13. The semiconductor device of claim 9, wherein the second stacked field-effect transistor structure comprises a backside source/drain contact disposed beneath a bottom source/drain region associated with the second lower field-effect transistor device.

14. The semiconductor device of claim 9, wherein the second stacked field-effect transistor structure comprises a first frontside source/drain contact for the second upper field-effect transistor device and a second frontside source/drain contact for the third upper field-effect transistor device.

15. The semiconductor device of claim 14, wherein the first frontside source/drain contact and the second frontside source/drain contact are connected to different back-end-of-line signal lines.

16. A method comprising:
forming first and second stacked field-effect transistor device structures, wherein the first stacked field-effect transistor device structure comprises a first plurality of channel layers corresponding to a first upper field-effect transistor device and a first lower field-effect transistor device, and the second stacked field-effect transistor device structure comprises a second plurality of channel layers corresponding to a second upper field-effect transistor device and a second lower field-effect transistor device;
forming a first gate cut portion disposed between the first and second stacked field-effect transistor device structures; and
dividing the second upper field-effect transistor device into a third upper field-effect transistor device and a fourth upper field-effect transistor device, wherein the dividing comprises dividing the channels layers corresponding to the second upper field-effect transistor device and forming a second gate cut portion between the third upper field-effect transistor device and the fourth upper field-effect transistor device.

17. The method of claim 16, further comprising:
forming a first frontside source/drain contact for the third upper field-effect transistor device, and a second frontside source/drain contact for the fourth upper field-effect transistor device.

18. The method of claim 17, wherein the first frontside source/drain contact and the second frontside source/drain contact are connected to different back-end-of-line signal lines.

19. The method of claim 16, further comprising:
forming a gate region that surrounds the channels layers corresponding to the third upper field-effect transistor device, the fourth upper field-effect transistor device, and the second lower field-effect transistor device.

20. The method of claim 16, further comprising:
forming a backside source/drain contact disposed beneath a bottom source/drain region associated with the second lower field-effect transistor device.
